(19) United States
(12) Patent Application Publication
(10) Pub. No.: US 2011/0272722 A1
(43) Pub. Date: Nov. 10, 2011

(54) ENCAPSULATION STRUCTURE FOR LIGHT-EMITTING DIODE

(76) Inventor: Hong-Yuan CHEN, Yonghe City (TW)

(21) Appl. No.: 12/775,972

(22) Filed: May 7, 2010

(51) Int. Cl. H01L 33/52; H01L 33/58

(52) U.S. Cl. 257/98; 257/100; 257/E33.059; 257/E33.061

(57) ABSTRACT

The present invention relates to an encapsulation structure for light-emitting diode, which includes an encapsulation base, at least one light-emitting diode chip, a first encapsulation material and a second encapsulation material. The encapsulation base includes an encapsulation region, and the light-emitting diode chips are mounted on the encapsulation region. The first encapsulation material is disposed on the encapsulation region and overlays the light-emitting diode chips. The second encapsulation material is doped with a predetermined amount of phosphor (fluorescent powder), and the second encapsulation material is superposed on the first encapsulation material. Hence, according to the structure described above, the present invention effectively enables customization of products, and reduces the stockpiling of semi-finished products.

### BACKGROUND OF THE INVENTION

(a) Field of the Invention

The present invention provides an encapsulation structure, and more particularly provides an encapsulation structure for light-emitting diode enabling customization, and reducing a stockpile of semi-finished products.

(b) Description of the Prior Art

Because LED (light-emitting diode) chips are provided with the advantages of high luminous efficiency, long serviceable life, are not easily damaged, have low power consumption, provide environmental protection and are small in size, thus, in recent years, the LED has already become the new light source with the greatest application potential. Nevertheless, the application aspect of LEDs was limited to indicator lights and display panels in the early period because the luminescent brightness was inadequate. However, in recent years, because of breakthroughs in material and packaging technology, there has been an enormous improvement in the brightness of LEDs, enabling LEDs to replace traditional light sources such as incandescent lamps, halogen lamps, fluorescent lamps, and the like.

In general, an encapsulation structure is required to protect the light-emitting diode chips when in use, and the light-emitting diode chips are mounted on an encapsulation base when carrying out encapsulation thereof. The encapsulation base comprises an encapsulation region, and the encapsulation region enables the light-emitting diode chips to be mounted thereon, after which the light-emitting bodies are overlaid with a layer of transparent encapsulation material. The transparent encapsulation material is generally material of good light transmission quality such as silicone, and the like, which also enables the transparent encapsulation material to protect the light-emitting diode chips. Moreover, the transparent encapsulation material is doped with an appropriate amount of phosphor (fluorescent powder) to provide the light-emitting diode chips with specific color temperature.

However, the following problems and shortcomings are still in need of improvement when using the aforementioned light-emitting diode chip encapsulation structure of the prior art:

The light-emitting diode chips are frequently produced according to the quantity ordered by the customer, however, problems in manufacturing yields require the manufacturer to manufacture superfluous light-emitting diode chips to meet customer requirements, which, at the same time, frequently results in an excessive stockpile for the manufacturer because of an excessive production of light-emitting diode chips of specific color temperature, causing waste in production.

Thus, it is the strong desire of the inventor and manufacturers engaged in related art and purpose of the present invention to research, improve and resolve the problems and shortcomings of the aforementioned prior art.

### SUMMARY OF THE INVENTION

Hence, in light of the shortcomings of the aforementioned prior art, the inventor of the present invention, having collected related data, and through evaluation and consideration from many aspects, as well as having accumulated years of experience in related arts, through continuous testing and improvements, has designed a new encapsulation structure for light-emitting diode enabling customization, and reducing a stockpile of semi-finished products.

The primary objective of the present invention is to provide an encapsulation structure enabling customization, and reducing a stockpile of semi-finished products.

In order to achieve the aforementioned objective, the present invention comprises an encapsulation base, at least one light-emitting diode chip, a first encapsulation material and a second encapsulation material. The encapsulation base comprises an encapsulation region, and the light-emitting diode chips are mounted on the encapsulation region. The first encapsulation material is disposed on the encapsulation region and overlays the light-emitting diode chips. The second encapsulation material is doped with a predetermined amount of phosphor (fluorescent powder), and the second encapsulation material is superposed on the first encapsulation material.

In which, the encapsulation base comprising the present invention incorporates the encapsulation region, and the encapsulation region of the encapsulation base enables the light-emitting diode chips to be mounted thereon. The light-emitting diode chips are overlaid with the first encapsulation material, and after encapsulation with the first encapsulation material is completed, then the semi-finished product produced can be stockpiled. The second encapsulation material can then be used to further overlay the first encapsulation material, in which the second encapsulation material can be doped with a predetermined amount of phosphor (fluorescent powder) according to customer needs. Accordingly, meeting customization needs can be achieved.

Moreover, because the present invention enables stockpiling of semi-finished products after completing encapsulation with the first encapsulation material, thus, further encapsulation with the second encapsulation material can be carried out according to the end product color temperature required by the customer. Accordingly, the manufacturer does not need to bear the burden of a huge stockpile. Hence, the present invention is provided with the practical advancement of reducing stockpiling of semi-finished products.

To enable a further understanding of said objectives and the technological methods of the invention herein, a brief description of the drawings is provided below followed by a detailed description of the preferred embodiments.

### BRIEF DESCRIPTION OF THE DRAWINGS

FIG. 1 shows an elevational view of a preferred embodiment of the present invention.

FIG. 2 shows an exploded elevational view of the preferred embodiment of the present invention.

FIG. 3 shows a cutaway view of the preferred embodiment of the present invention.

FIG. 4 shows an implementation schematic view I of the preferred embodiment of the present invention.

FIG. 5 shows an implementation schematic view II of the preferred embodiment of the present invention.

### DETAILED DESCRIPTION OF THE PREFERRED EMBODIMENTS

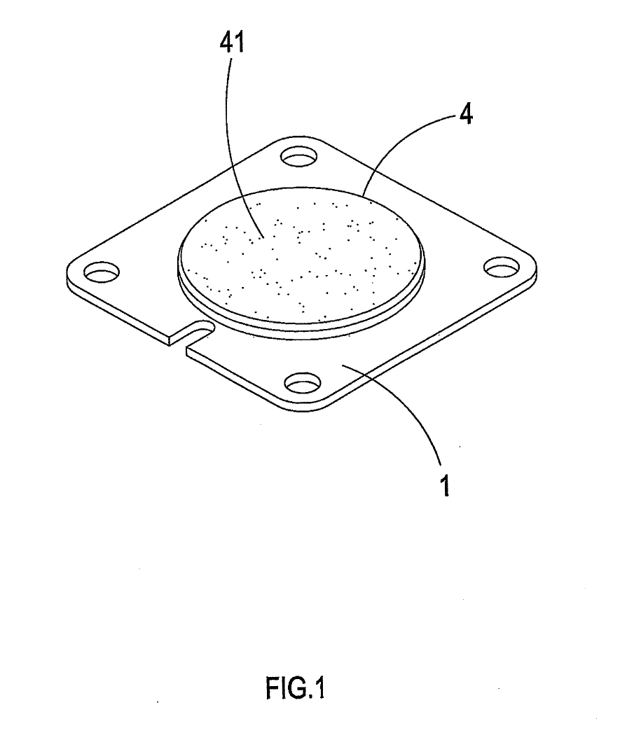

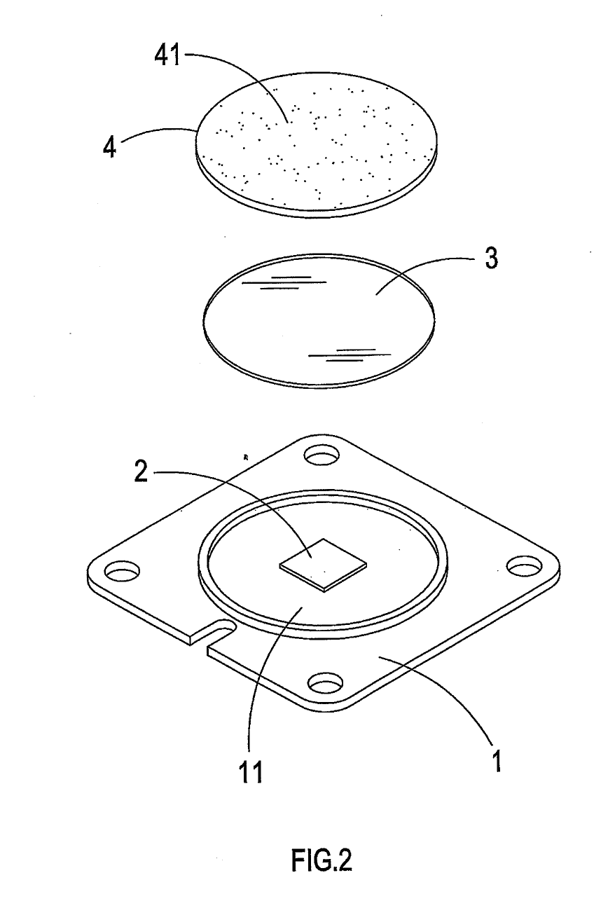

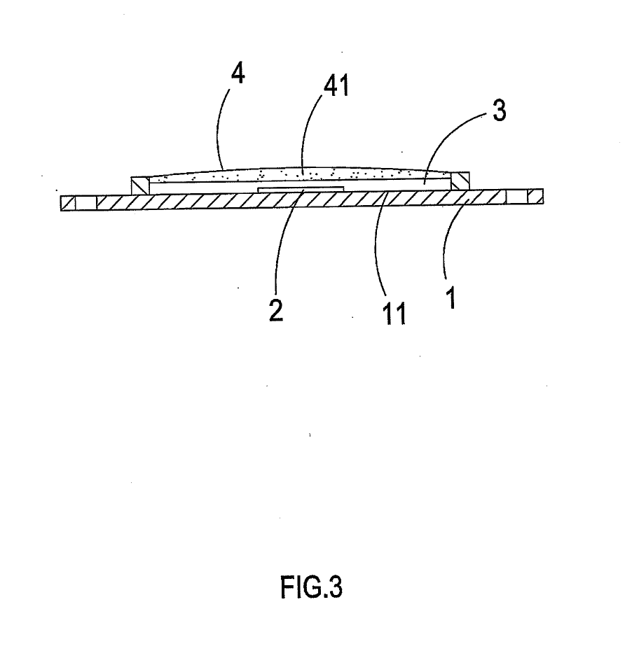

Referring to FIG. 1, FIG. 2 and FIG. 3, which show an elevational view, an exploded elevational view and a cutaway view respectively of a preferred embodiment of the present invention, and it can be clearly seen from the drawings that the present invention comprises:

An encapsulation base 1, and the encapsulation base 1 comprises an encapsulation region 11.

At least one light-emitting diode chip 2, and the light-emitting diode chips 2 are mounted on the encapsulation region 11.

A first encapsulation material 3, and the first encapsulation material 3 is disposed on the encapsulation region 11. The first encapsulation material 3 overlays the light-emitting diode chips 2, and the first encapsulation material 3 can be silicone or epoxy resin or acrylic or a combination thereof, or related material having good light transmission quality.

A second encapsulation material 4, and the second encapsulation material 4 is doped with a predetermined amount of phosphor (fluorescent powder) 41. The second encapsulation material 4 is superposed on the first encapsulation material 3, and the second encapsulation material 4 can be silicone or epoxy resin or acrylic or a combination thereof, or related material having good light transmission quality.

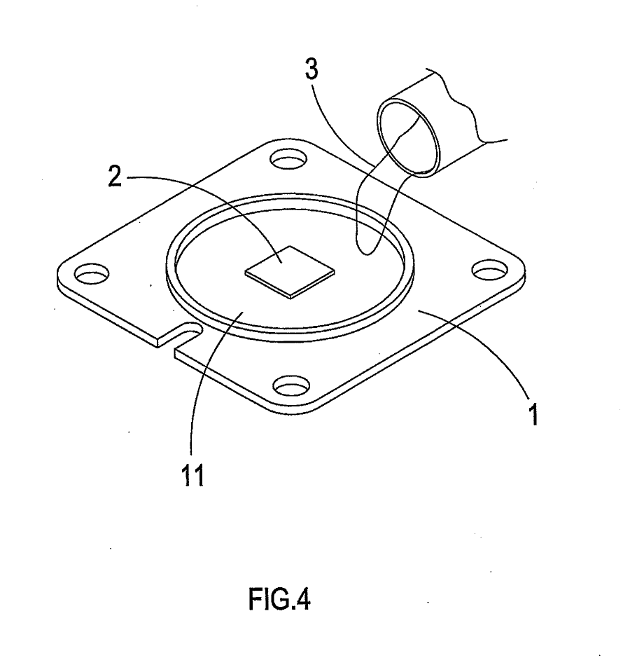

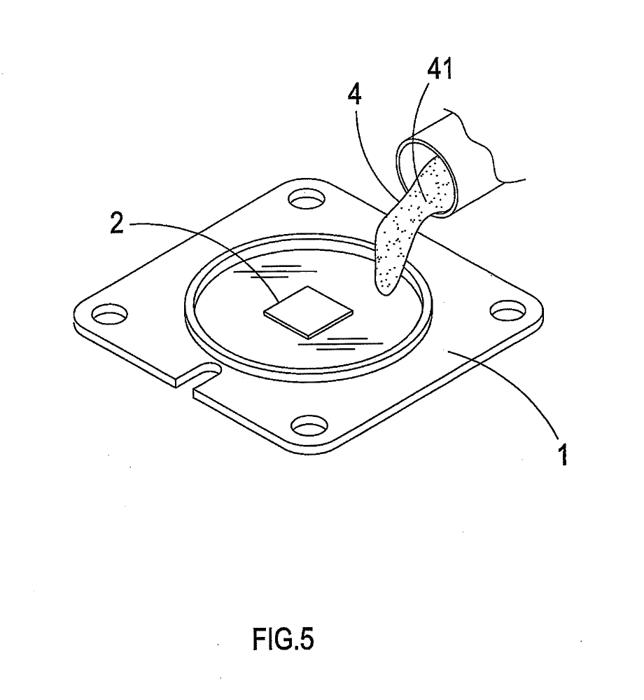

According to the aforementioned structure and constructional design, circumstances during operational use of the present invention are described hereinafter. Referring together to FIG. 3, FIG. 4 and FIG. 5, which show a cutaway view, and implementation schematic views I and II respectively of the preferred embodiment of the present invention, and it can be clearly seen from the drawings that the present invention comprises the encapsulation base 1, and when encapsulating the light-emitting diode chips 2, the light-emitting diode chips 2 are first mounted on the encapsulation region 11 of the encapsulation base 1, and the first encapsulation material 3 is then used to overlay the light-emitting diode chips 2, thereby completing a semi-finished product of the present invention. The manufacturer can stockpile these semi-finished product material, thus avoiding producing products exceeding that required by customers, and enabling further encapsulation with the second encapsulation material 4 according to the actual needs of customers. And because the second encapsulation material 4 is doped with a predetermined amount of the phosphor (fluorescent powder) 41, thus, the present invention is able to change the amount of phosphor (fluorescent powder) 41 whenever necessary according to the actual needs of customers, thereby further controlling the color temperature emitted by the light-emitting diode chips 2 of the present invention to conform with the product required by customers.

Hence, referring to all the drawings, compared to the prior art, the following advantages exist when using the present invention:

The present invention uses a two layer sectioned structure comprising the first encapsulation material 3 and the second encapsulation material 4, which enables effectively reducing a stockpile of customer semi-finished products. Moreover, the manufacturer is able to freely adjust the amount of the phosphor (fluorescent powder) 41 in the second encapsulation material 4 to conform with the actual needs of customers.

In conclusion, the encapsulation structure for light-emitting diode of the present invention is clearly able to achieve the effectiveness and objectives as disclosed when in use, and is indeed a practical and exceptional invention that complies with the essential elements as required for a new patent application. Accordingly, a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. An encapsulation structure for light-emitting diode, comprising:
an encapsulation base, the encapsulation base comprises an encapsulation region;
at least one light-emitting diode chip, the one light-emitting diode chips are mounted on the encapsulation region;
a first encapsulation material, the first encapsulation material is disposed on the encapsulation region, and the first encapsulation material overlays the light-emitting diode chip;
a second encapsulation material, the second encapsulation material is doped with a predetermined amount of phosphor (fluorescent powder), and the second encapsulation material is superposed on first encapsulation material;
wherein, the second encapsulation material is used to freely determine the desired amount of doping of the phosphor (fluorescent powder), thereby enabling achieving the effectiveness of customization.

2. The encapsulation structure for light-emitting diode according to claim 1, wherein the first encapsulation material is silicone or epoxy resin or acrylic or a combination thereof.

3. The encapsulation structure for light-emitting diode according to claim 1, wherein the second encapsulation material is silicone or epoxy resin or acrylic or a combination thereof.
